(19) United States
(12) Patent Application Publication
(10) Pub. No.: US 2025/0194171 A1
(43) Pub. Date: Jun. 12, 2025

(54) SEMICONDUCTOR DEVICE

(71) Applicant: SK hynix Inc., Gyeonggi-do (KR)

(72) Inventors: Dong Soo KIM, Gyeonggi-do (KR); Yoon Jae NAM, Gyeonggi-do (KR); Dae Jin KIM, Gyeonggi-do (KR); Mun Gi SIM, Gyeonggi-do (KR)

(21) Appl. No.: 18/916,702

(22) Filed: Oct. 16, 2024

(30) Foreign Application Priority Data
Dec. 8, 2023 (KR) 10-2023-0177313

(51) Int. Cl. H01L 29/06; H01L 29/423; H01L 29/49

(52) U.S. Cl. CPC H10D 62/102; H10D 64/513; H10D 64/661; H10D 64/667

(57) ABSTRACT

A semiconductor device includes a trench formed in a substrate; a first gate electrode filling a lower portion of the trench, and the first gate electrode containing a trap passivation material; and a second gate electrode formed over the first gate electrode, and the second gate electrode containing the trap passivation material. The reliability of semiconductor devices may be improved by applying a gate electrode containing a trap passivation material. The resistance of a word line may be reduced by applying a gate electrode containing a metal material. The gate-induced drain leakage (GIDL) may be reduced by adjusting the work functions of the upper and lower gate electrodes.

### CROSS-REFERENCE TO RELATED APPLICATIONS

The present application claims priority under 35 U.S.C 119 (a) to Korean Patent Application No. 10-2023-0177313, filed on Dec. 8, 2023, which is incorporated herein by reference in its entirety.

### BACKGROUND

### 1. Field

Various embodiments of the present disclosure relate generally to a semiconductor device and, more particularly, to a semiconductor device including a buried gate.

### 2. Description of the Related Art

Generally, a metal gate electrode may be used for high performance transistors. Moreover, buried gate-type transistors require controlling the threshold voltage for high-performance operation. Also, Gate Induced Drain Leakage (GIDL) characteristics have a significant influence on the performance of the buried gate transistor. As the performance requirements for electronic devices continue to become more demanding, so, also, do the performance and electrical characteristic requirements of semiconductor devices and their transistors.

### SUMMARY

In accordance with an embodiment of the present disclosure, a semiconductor device includes: a trench formed in a substrate; a first gate electrode filling a lower portion of the trench, the first gate electrode containing a trap passivation material; and a second gate electrode formed over the first gate electrode, the second gate electrode containing the trap passivation material.

In accordance with another embodiment of the present disclosure, a method for fabricating a semiconductor device includes: forming a trench in a substrate; forming a gate dielectric layer suitable for covering the sidewalls and bottom surface of the trench; forming a first gate electrode using a source gas containing a trap passivation material to gap-fill the lower portion of the trench over the gate dielectric layer; forming a second gate electrode using a source gas containing a trap passivation material to gap-fill the middle portion of the trench over the first gate electrode.

### BRIEF DESCRIPTION OF THE DRAWINGS

FIG. 1 is a plan view illustrating semiconductor devices in accordance with embodiments of the present disclosure.

FIG. 2A is a cross-sectional view illustrating a semiconductor device taken along a line A-A′ of FIG. 1 in accordance with a first embodiment of the present disclosure.

FIG. 2B is a cross-sectional view illustrating the semiconductor device taken along a line B-B′ of FIG. 1 in accordance with the first embodiment of the present disclosure.

FIGS. 3 and 4 illustrate semiconductor devices in accordance with second and third embodiments of the present disclosure.

FIGS. 5 and 6 illustrate semiconductor devices in accordance with fourth and fifth embodiments of the present disclosure.

FIGS. 7A to 7D are process cross-sectional views illustrating a method for fabricating a semiconductor device in accordance with a first embodiment of the present disclosure.

### DETAILED DESCRIPTION

Various embodiments of the present disclosure will be described below in more detail with reference to the accompanying drawings. The embodiments of the present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

The drawings are not necessarily to scale and in some instances, proportions may have been exaggerated to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

Embodiments of the present disclosure are directed to a semiconductor device with improved performance characteristics and, in particular, improved electrical characteristics.

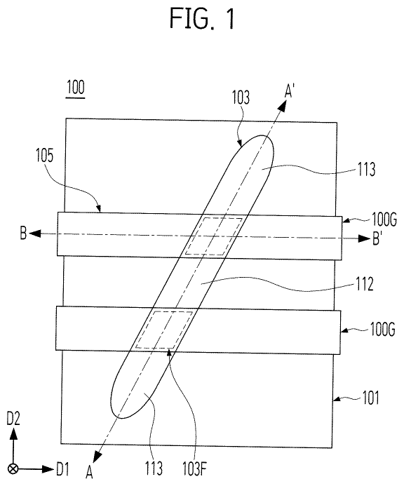

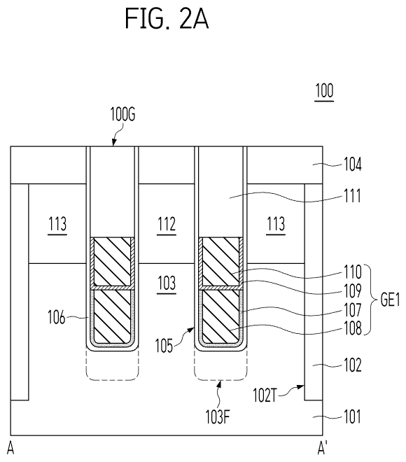

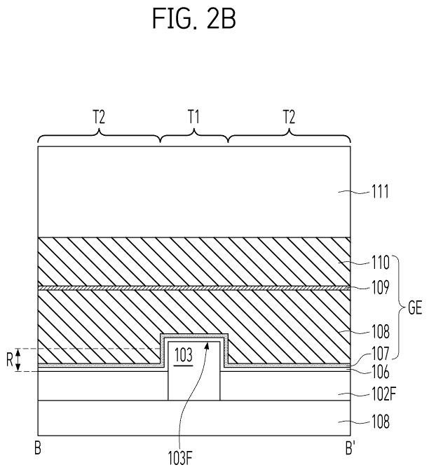

FIG. 1 is a plan view illustrating semiconductor devices in accordance with embodiments of the present disclosure. FIG. 2A is a cross-sectional view illustrating a semiconductor device taken along a line A-A′ of FIG. 1 in accordance with a first embodiment of the present disclosure. FIG. 2B is a cross-sectional view illustrating the semiconductor device taken along a line B-B′ of FIG. 1 in accordance with the first embodiment of the present disclosure.

Referring to FIGS. 1, 2A, and 2B, the semiconductor device 100 in accordance with the first embodiment of the present disclosure may include a substrate 101 and a buried gate structure 100G embedded in the substrate 101. The semiconductor device 100 may be part of a memory cell. For example, the semiconductor device 100 may be part of a Dynamic Random Access Memory (DRAM) memory cell.

The substrate 101 may be a material appropriate for semiconductor processing. The substrate 101 may include a semiconductor substrate. The substrate 101 may include a material containing silicon. The substrate 101 may include silicon, monocrystalline silicon, polysilicon, amorphous silicon, silicon germanium, monocrystalline silicon germanium, polycrystalline silicon germanium, carbon-doped silicon, a combination thereof, or a multi-layer thereof. The substrate 101 may also include other semiconductor materials, such as germanium. The substrate 101 may include a III/V-group semiconductor substrate, for example, a compound semiconductor substrate, such as GaAs. The substrate 101 may include a Silicon-On-Insulator (SOI) substrate.

An isolation layer 102 and an active region 103 may be formed over the substrate 101. The active region 103 may be defined by the isolation layer 102. The isolation layer 102 may be a Shallow Trench Isolation (STI) region that is formed by a trench etching process. The isolation layer 102 may be formed by filling a shallow trench, for example, an isolation trench 102T, with a dielectric material. The isolation layer 102 may include, for example, silicon oxide, silicon nitride, or a combination thereof.

A trench 105 may be formed in the substrate 101. The trench 105 may be formed by using a hard mask layer 104 as an etch barrier and etching the substrate 101. From the perspective of a top view of FIG. 1, the trench 105 may have a line shape extending in a D1 direction. The trench 105 may have a line shape crossing the active region 103 and the isolation layer 102. The trench 105 may have a shallower depth than that of the isolation trench 102T. According to another embodiment of the present disclosure, the bottom portion of the trench 105 may have a curvature. The trench 105 may be a space where the buried gate structure 100G is formed, and it may be referred to as a ‘gate trench’.

A first doped region 112 and a second doped region 113 may be formed in the active region 103. The first doped region 112 and the second doped region 113 may be regions doped with a conductive dopant. For example, the conductive dopant may include phosphorus (P), arsenic (As), antimony (Sb), or boron (B). The first doped region 112 and the second doped region 113 may be doped with dopants of the same conductivity type. The first doped region 112 and the second doped region 113 may be disposed in the active region 103 on both sides of the trench 105. The bottom surfaces of the first doped region 112 and the second doped region 113 may be disposed at a predetermined depth from the top surface of the active region 103. The bottom surfaces of the first doped region 112 and the second doped region 113 may be higher than the bottom surface of the trench 105. The first doped region 112 may be referred to as a ‘first source/drain region, and the second doped region 113 may be referred to as a ‘second source/drain region.’ A channel may be defined between the first doped region 112 and the second doped region 113 by the buried gate structure 100G. The channel may be defined on the profile of the trench 105.

The trench 105 may include a first trench T1 and a second trench T2. The first trench T1 may be formed in the active region 103. The second trench T2 may be formed in the isolation layer 102. The trench 105 may continuously extend from the first trench T1 to the second trench T2. In the trench 105, the bottom surface of the first trench T1 may be disposed at a higher level than the bottom surface of the second trench T2. The height difference between the first trench T1 and the second trench T2 may be formed as the isolation layer 102 is recessed. Accordingly, the second trench T2 may include a recess region R having a lower bottom surface than the bottom surface of the first trench T1. A fin 103F may be formed in the active region 103 due to the height difference between the first trench T1 and the second trench T2. Accordingly, the active region 103 may include a fin 103F.

In this way, the fin 103F may be formed below the first trench T1, and the side wall of the fin 103F may be exposed by the recessed isolation layer 102F. The fin 103F may be a portion where a portion of the channel (not shown) is formed. The fin 103F may be called a saddle fin. The channel width may be increased by the fin 103F, and the electrical characteristics may be improved.

According to another embodiment of the present disclosure, the fin 103F may be omitted.

The buried gate structure 100G may include a gate dielectric layer 106 that covers the bottom surface and side walls of the trench 105, and a gate electrode structure GE1 and a capping layer 111. The gate electrode structure GE1 and the capping layer 111 may fill the trench 105 over the gate dielectric layer 106. The gate electrode structure GE1 and the capping layer 111 may be sequentially stacked over the gate dielectric layer 106.

The gate dielectric layer 106 may include, for example, silicon oxide, silicon nitride, silicon oxynitride, a high-k material, or a combination thereof. The high-k material may include a material having a greater dielectric constant than that of the silicon oxide. For example, the high-k material may include a material having a greater dielectric constant than approximately 3.9. For another example, the high-k material may include a material having a dielectric constant that is greater than approximately 10. For another example, the high-k material may include a material having a dielectric constant of approximately 10 to approximately 30. The high-k material may include at least one metallic element. The high-k material may include a hafnium-containing material. The hafnium-containing material may include hafnium oxide, hafnium silicon oxide, hafnium silicon oxynitride, or a combination thereof. According to another embodiment of the present disclosure, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may selectively be used. The gate dielectric layer 106 may include a metal oxide.

The top surface of the gate electrode structure GE1 may be disposed at a lower level than the top surface of the active region 103. The gate electrode structure GE1 may include a stacked structure of the first gate electrode 108 and the second gate electrode 110. The first gate electrode 108 and the second gate electrode 110 may include the same metal. The gate electrode structure GE1 may include a first barrier layer 107 that covers both side walls and the bottom surface of the first gate electrode 108 between the gate dielectric layer 106 and the first gate electrode 108. The gate electrode structure GE1 may include a second barrier layer 109 that covers both side walls and the bottom surface of the second gate electrode 110 between the first gate electrode 108 and the second gate electrode 110 and between the gate dielectric layer 106 and the second gate electrode 110.

Thus, the gate electrode structure GE1 may include a stacked structure of a liner-type first barrier layer 107, a bulk-type first gate electrode 108 covered by the first barrier layer 107, a liner-type second barrier layer 109 disposed over the first gate electrode 108, and a bulk-type second gate electrode 110 covered by the second barrier layer 109. The top surfaces of the first barrier layer 107 and the first gate electrode 108 may be disposed at the same level. The top surfaces of the second barrier layer 109 and the second gate electrode 110 may be disposed at the same level. The top surface of the second gate electrode 110 may be disposed at a lower level than the top surface of the substrate 101. The second gate electrode 110 may partially overlap with the first and second doped regions 112 and 113 in the horizontal direction.

The first barrier layer 107 may prevent oxidation of the first gate electrode 108 and prevent out-diffusion of metal ions of the first gate electrode 108. To this end, the first barrier layer 107 may include a material that is less oxidized than the first gate electrode 108 and prevents diffusion of the first gate electrode 108. Thus, the first barrier layer 107 may include a material having a lower electronegativity than the first gate electrode 108 for preventing oxidation and out-diffusion of the first gate electrode 108. The first barrier layer 107 may include a high work function material. The first barrier layer 107 may include a metal nitride. For example, the first barrier layer 107 may include one metal nitride selected from among molybdenum nitride (MON), titanium nitride (TiN), and tantalum nitride (TaN).

The first gate electrode 108 may fill the lower portion of the trench 105 over the first barrier layer 107. The first gate electrode 108 may include, for example, a metal material. In particular, according to an embodiment of the present disclosure the first gate electrode 108 may include a metal material containing a trap passivation material. The trap passivation material contained in the first gate electrode 108 may be diffused into the surrounding material. The trap passivation material may be diffused into the inside of the gate dielectric layer 106 or into the interface between the gate electrode structure GE1 and the gate dielectric layer 106. The diffused trap passivation material may passivate trap sites. Accordingly, the retention and the row hammer characteristics of the semiconductor device may be improved.

The trap passivation material may be diffused by a subsequent thermal process. For example, the subsequent thermal process may be provided while a bit line structure and a capacitor are formed after the buried gate structure 100G is formed.

According to an embodiment of the present disclosure, the trap passivation material may include fluorine (F). According to an embodiment of the present disclosure, the first gate electrode 108 may include a metal material containing fluorine. According to an embodiment of the present disclosure, the first gate electrode 108 may include molybdenum (Mo) containing fluorine. According to an embodiment of the present disclosure, the first gate electrode 108 may include molybdenum tetrafluoride (MoF₄)-based molybdenum. Thus, the first gate electrode 108 may include a molybdenum layer that is formed by using molybdenum tetrafluoride (MoF₄) as a source gas.

According to an embodiment of the present disclosure the content of the trap passivation material contained in the first gate electrode 108 may be adjusted in a range so that the electrical characteristics of a semiconductor device are not deteriorated.

As a comparative example, tungsten hexafluoride (WF₆)-based tungsten may deteriorate the electrical characteristics of a semiconductor device due to excessive fluorine. As another comparative example, since molybdenum tetrachloride (MoCl₄)-based molybdenum does not contain fluorine, the trap passivation effect that may be obtained from fluorine may not be obtained. On the other hand, according to an embodiment of the present disclosure molybdenum formed by using molybdenum tetrafluoride (MoF₄) as the source gas may be used as the first gate electrode 108. Therefore, the trap passivation effect may be obtained without deteriorating the characteristics of the semiconductor device due to the excessive fluorine.

The second barrier layer 109 may include the same material as that of the first barrier layer 107. The second barrier layer 109 may prevent oxidation of the second gate electrode 110 and prevent out-diffusion of the metal material of the second gate electrode 110. To this end, the second barrier layer 109 may include a material that is less oxidized than the second gate electrode 110 and prevents diffusion of the second gate electrode 110. Thus, the second barrier layer 109 may include a material having a lower electronegativity than the second gate electrode 110 for preventing oxidation and out-diffusion of the second gate electrode 110. The second barrier layer molybdenum nitride (MON), titanium nitride (TIN), and tantalum nitride (TaN).

According to another embodiment of the present disclosure, the second barrier layer 109 may include a low work function material.

According to another embodiment of the present disclosure, the second barrier layer 109 may include a material which is different from the first barrier layer 107. The second barrier layer 109 may include a silicon-based material. For example, the second barrier layer 109 may include polysilicon.

The second gate electrode 110 may include the same material as that of the first gate electrode 108. The second gate electrode 110 may fill the middle portion of the trench 105 over the first gate electrode 108. The second gate electrode 110 may include, for example, a metal material. In particular, according to an embodiment of the present disclosure the second gate electrode 110 may include a metal material containing a trap passivation material. The trap passivation material contained in the second gate electrode 110 may be diffused into the surrounding materials. The trap passivation material may be diffused into the inside of the gate dielectric layer 106 or into the interface between the gate electrode structure GE1 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 100G is formed.

According to an embodiment of the present disclosure, the trap passivation material may include fluorine (F). According to an embodiment of the present disclosure, the second gate electrode 110 may include a metal material containing fluorine. According to an embodiment of the present disclosure, the second gate electrode 110 may include molybdenum (Mo) containing fluorine. According to an embodiment of the present disclosure, the second gate electrode 110 may include molybdenum fluoride (MoF₄)-based molybdenum. Thus, the second gate electrode 110 may include a molybdenum layer which is formed by using molybdenum fluoride (MoF₄) as a source gas.

According to an embodiment of the present disclosure the content of the trap passivation material contained in the second gate electrode 110 may be adjusted in a range so that the electrical characteristics of the semiconductor device are not deteriorated.

The capping layer 111 may fill the upper portion of the trench 105 over the second gate electrode. The capping layer 111 may include a dielectric material. For example, the capping layer 111 may include silicon nitride, silicon oxide, silicon oxynitride, or a combination thereof.

According to an embodiment of the present disclosure the lower portion, middle portion, and upper portion of the trench 105 are provided for the sake of convenience in description, and the thickness (or depth) of each portion may be the same or different from each other.

According to an embodiment of the present disclosure the resistance of the gate electrode structure GE1 may be reduced by forming the first and second gate electrodes 108 and 110 of a metal material. Also, Gate Induced Drain Leakage (GIDL) may be reduced and retention may be improved by applying the second barrier layer 109 that covers both side walls of the second gate electrode 110. In particular, according to an embodiment of the present disclosure a trap disposed at the interface between the substrate 101 and the gate dielectric layer 106 may be passivated by forming the first and second gate electrodes 108 and 110 of a metal material containing a trap passivation material. Therefore, the row hammer and the retention may be improved.

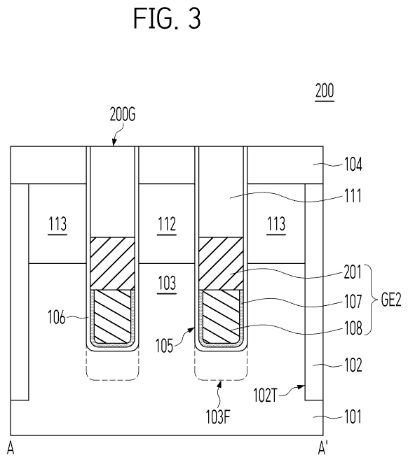

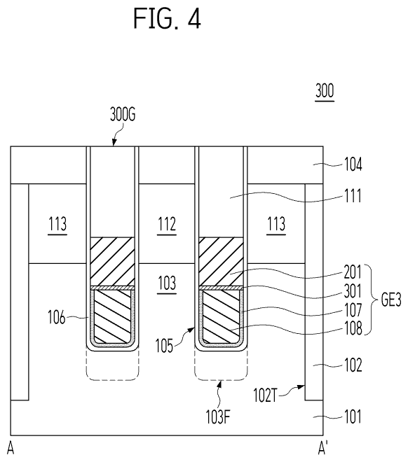

FIGS. 3 and 4 illustrate semiconductor devices in accordance with second and third embodiments of the present disclosure. FIGS. 3 and 4 may include the same constituent elements as those shown in FIG. 2A except for the second gate electrode. Thus, the substrate 101, the isolation layer 102, the active region 103, the hard mask layer 104, the gate dielectric layer 106, the capping layer 111, the first doped region 112, and the second doped region 113 illustrated in FIGS. 3 and 4 may have the same materials and structures as those of FIG. 2A, and detailed description on them will be omitted.

Referring to FIG. 3, the semiconductor device 200 in accordance with the second embodiment of the present disclosure may include a substrate 101 and a buried gate structure 200G embedded in the substrate 101.

The buried gate structure 200G may include a gate dielectric layer 106 that covers the bottom surface and side walls of the trench 105, and a gate electrode structure GE2 and a capping layer 111 that are sequentially stacked to fill the trench 105 over the gate dielectric layer 106. The gate electrode structure GE2 may include a stacked structure of a first barrier layer 107, a first gate electrode 108, and a second gate electrode 201. The first gate electrode 108 may fill the lower portion of the trench 105 over the first barrier layer 107. The second gate electrode 201 may be formed over the first gate electrode 108 and may fill the middle portion of the trench 105. The capping layer 111 may fill the upper portion of the trench 105 over the second gate electrode 201. The lower portion, middle portion, and upper portion of the trench 105 may be provided for the sake of convenience in description, and the thickness (or depth) of each portion may be the same or different from each other.

The top surface of the gate electrode structure GE2 may be disposed at a lower level than the top surface of the active region 103. The top surface of the first gate electrode 108 may be disposed at a lower level than the bottom surfaces of the first and second doped regions 112 and 113. The top surface of the second gate electrode 201 may be disposed at a higher level than the bottom surfaces of the first and second doped regions 112 and 113. Thus, the second gate electrode 201 may partially overlap with the first and second doped regions 112 and 113 in the horizontal direction (a direction parallel to the top surface of the substrate).

The first barrier layer 107 may prevent oxidation of the first gate electrode 108 and out-diffusion of the metal ions of the first gate electrode 108. To this end, the first barrier layer 107 may include a material that is less oxidized than the first gate electrode 108 and prevents diffusion of the first gate electrode 108. Thus, the first barrier layer 107 may include a material having a lower electronegativity than the first gate electrode 108 for preventing oxidation and out-diffusion of the first gate electrode 108. The first barrier layer 107 may include a metal nitride. For example, the first barrier layer 107 may include one metal nitride selected from among molybdenum nitride (MON), titanium nitride (TiN), and tantalum nitride (TaN).

The first gate electrode 108 may fill the lower portion of the trench 105 over the first barrier layer 107. The first gate electrode 108 may include, for example, a metal material. In particular, according to an embodiment of the present disclosure the first gate electrode 108 may include a metal material containing a trap passivation material. The trap passivation material contained in the first gate electrode 108 may be diffused into the surrounding materials. The trap passivation material may be diffused into the inside of the gate dielectric layer 106 or into the interface between the gate electrode structure GE2 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 200G is formed.

According to an embodiment of the present disclosure, the trap passivation material may include fluorine (F). According to an embodiment of the present disclosure, the first gate electrode 108 may include a metal material containing fluorine. According to an embodiment of the present disclosure, the first gate electrode 108 may include molybdenum (Mo) containing fluorine. According to an embodiment of the present disclosure, the first gate electrode 108 may include molybdenum tetrafluoride (MoF₄)-based molybdenum. Thus, the first gate electrode 108 may include a molybdenum layer that is formed by using molybdenum tetrafluoride (MoF₄) as a source gas.

According to an embodiment of the present disclosure the content of the trap passivation material contained in the first gate electrode 108 may be adjusted in a range so that the electrical characteristics of the semiconductor device are not deteriorated.

The second gate electrode 201 may include, for example, a metal material. In particular, according to an embodiment of the present disclosure the second gate electrode 201 may include a metal material containing a trap passivation material. The trap passivation material contained in the second gate electrode 201 may be diffused into the surrounding materials. The trap passivation material may be diffused into the inside of the gate dielectric layer 106 or into the interface between the second gate electrode 201 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 200G is formed.

According to an embodiment of the present disclosure, the trap passivation material may include fluorine (F). According to an embodiment of the present disclosure, the second gate electrode 201 may include a metal material containing fluorine. According to an embodiment of the present disclosure, the second gate electrode 201 may include titanium nitride (TiN) containing fluorine. According to an embodiment of the present disclosure, the second gate electrode 201 may include titanium tetrafluoride (TiF₄)-based titanium nitride. Thus, the second gate electrode 201 may include titanium nitride that is formed by using titanium tetrafluoride (TiF₄) as the source gas.

According to an embodiment of the present disclosure the content of the trap passivation material contained in the second gate electrode 201 may be adjusted in a range so that the electrical characteristics of the semiconductor device are not deteriorated.

According to another embodiment of the present disclosure, referring to FIG. 4, a buried gate structure 300G may include a gate electrode structure GE3 and a capping layer 111 over the gate electrode structure GE3. The gate electrode structure GE3 may further include an interface layer 301 at the interface between the first gate electrode 108 and the second gate electrode 201. The interface layer 301 may be applied to form a stable interface by preventing ion diffusion or reaction that may occur at the interface between the first gate electrode 108 and the second gate electrode 201. The interface layer 301 may include a silicon-based material. The interface layer 301 may include, for example, silicon oxide or polysilicon. The interface layer 301 may be formed to have a thickness that allows electrical conduction between the first gate electrode 108 and the second gate electrode 201.

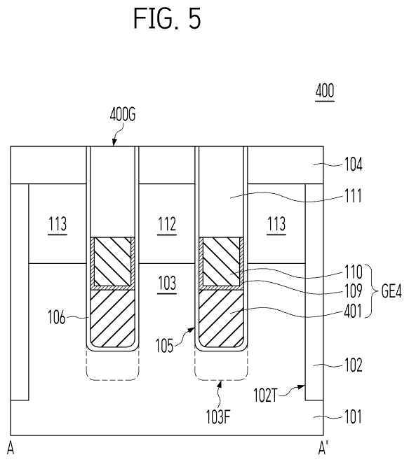

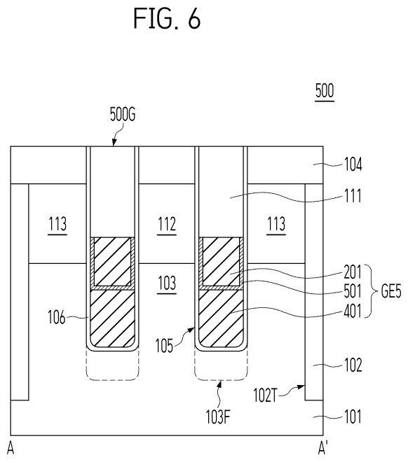

FIGS. 5 and 6 illustrate semiconductor devices in accordance with fourth and fifth embodiments of the present disclosure. FIGS. 5 and 6 may include the same constituent elements as those of FIG. 2A except for the constituent elements of the gate electrode structure illustrated in each figure. Thus, the substrate 101, the isolation layer 102, the active region 103, the hard mask layer 104, the gate dielectric layer 106, the capping layer 111, the first doped region 112, and the second doped region 113 illustrated in FIGS. 5 and 6 may have the same materials and structures as those shown in FIG. 2A, and detailed description on them will be omitted.

Referring to FIG. 5, the semiconductor device 400 in accordance with the fourth embodiment of the present disclosure may include the same constituent elements as those of FIG. 2A except for the first gate electrode 401. The semiconductor device 400 may include a substrate 101 and a buried gate structure 400G embedded in the substrate 101.

The buried gate structure 400G may include a gate dielectric layer 106 that covers the bottom surface and side walls of the trench 105, and a gate electrode structure GE4 and a capping layer 111 that are sequentially stacked to fill the trench 105 over the gate dielectric layer 106.

The top surface of the gate electrode structure GE4 may be disposed at a lower level than the top surface of the active region 103. The gate electrode structure GE4 may include a stacked structure of the first gate electrode 401 and the second gate electrode 110. The gate electrode structure GE4 may include a second barrier layer 109 that covers both side walls and the bottom surface of the second gate electrode 110. Thus, the gate electrode structure GE4 may include a stacked structure of a first gate electrode 401, a liner-type second barrier layer 109, and a bulk-type second gate electrode 110.

The first gate electrode 401 may fill the lower portion of the trench 105 over the gate dielectric layer 106. The first gate electrode 401 may include, for example, a metal material. In particular, according to an embodiment of the present disclosure the first gate electrode 401 may include a metal material containing a trap passivation material. The trap passivation material contained in the first gate electrode 401 may be diffused into the surrounding materials. The trap passivation material may be diffused into the inside of the gate dielectric layer 106 or into the interface between the first gate electrode 401 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 400G is formed.

According to an embodiment of the present disclosure, the trap passivation material may include fluorine (F). According to an embodiment of the present disclosure, the first gate electrode 401 may include a metal material containing fluorine. According to an embodiment of the present disclosure, the first gate electrode 401 may include titanium nitride (TIN) containing fluorine. According to an embodiment of the present disclosure, the first gate electrode 401 may include titanium tetrafluoride (TiF₄)-based titanium nitride. Thus, the first gate electrode 401 may include titanium nitride that is formed by using titanium tetrafluoride (TiF₄) as the source gas.

According to an embodiment of the present disclosure the content of the trap passivation material contained in the first gate electrode 401 may be adjusted in a range so that the electrical characteristics of the semiconductor device are not deteriorated.

As a comparative example, tungsten hexafluoride (WF₆)-based tungsten may deteriorate the electrical characteristics of a semiconductor device due to excessive fluorine. As another comparative example, since titanium tetrachloride (MoCl₄)-based titanium nitride does not contain fluorine, the trap passivation effect that may be obtained from fluorine may not be obtained. In contrast, according to an embodiment of the present disclosure since titanium nitride that is formed by using titanium tetrafluoride (TiF₄) as the source gas is used as the first gate electrode 401, the trap passivation effect may be obtained without deteriorating the characteristics of the semiconductor device due to excessive fluorine.

The second barrier layer 109 may include the same material as that of the first barrier layer 107. The second barrier layer 109 may prevent oxidation of the second gate electrode 110 and out-diffusion of the metal ions of the second gate electrode 110. To this end, the second barrier layer 109 may include a material that is less oxidized than the second gate electrode 110 and prevents diffusion of the second gate electrode 110. Thus, the second barrier layer 109 may include a material having a lower electronegativity than the second gate electrode 110 for preventing oxidation and out-diffusion of the second gate electrode 110. The second barrier layer 109 may include a metal nitride, such as, for example, one metal nitride selected from among molybdenum nitride (MON), titanium nitride (TiN), and tantalum nitride (TaN).

According to another embodiment of the present disclosure, the second barrier layer 109 may include a different material than the material of the first barrier layer 107. The second barrier layer 109 may include a low work function material. The second barrier layer 109 may include a silicon-based material. For example, the second barrier layer 109 may include polysilicon.

The second gate electrode 110 may include, for example, a metal material. In particular, according to an embodiment of the present disclosure the second gate electrode 110 may include a metal material containing a trap passivation material. The trap passivation material contained in the second gate electrode 110 may be diffused into the surrounding materials. The trap passivation material may be diffused into the inside of the gate dielectric layer 106 or into the interface between the gate electrode structure GE4 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 400G is formed.

According to an embodiment of the present disclosure, the trap passivation material may include fluorine (F). According to an embodiment of the present disclosure, the second gate electrode 110 may include a metal material containing fluorine. According to an embodiment of the present disclosure, the second gate electrode 110 may include molybdenum (Mo) containing fluorine. According to an embodiment of the present disclosure, the second gate electrode 110 may include molybdenum tetrafluoride (MoF₄)-based molybdenum. Thus, the second gate electrode 110 may contain molybdenum that is formed by using molybdenum tetrafluoride (MoF₄) as the source gas.

According to an embodiment of the present disclosure the content of the trap passivation material contained in the second gate electrode 110 may be adjusted in a range that the electrical characteristics of the semiconductor device are not deteriorated.

Referring to FIG. 6, the semiconductor device 500 in accordance with the fifth embodiment of the present disclosure may include a substrate 101 and a buried gate structure 500G embedded in the substrate 101.

The buried gate structure 500G may include a gate dielectric layer 106 that covers the bottom surface and side walls of the trench 105, and a gate electrode structure GE5 and a capping layer 111 that are sequentially stacked to fill the trench 105 over the gate dielectric layer 106.

The top surface of the gate electrode structure GE5 may be disposed at a lower level than the top surface of the active region 103. The gate electrode structure GE5 may include a stacked structure of the first gate electrode 401 and the second gate electrode 201. The gate electrode structure GE5 may include a low work function layer 501 that covers both side walls and the bottom surface of the second gate electrode 201. Thus, the gate electrode structure GE5 may include a stacked structure of a first gate electrode 401, a liner-type low work function layer 501, and a bulk-type second gate electrode 201.

The first gate electrode 401 may include, for example, a metal material. In particular, according to an embodiment of the present disclosure, the first gate electrode 401 may include a metal material containing a trap passivation material. The trap passivation material contained in the first gate electrode 401 may be diffused into the surrounding materials. The trap passivation material may be diffused into the inside of the gate dielectric layer 106 or into the interface between the first gate electrode 401 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 500G is formed.

According to an embodiment of the present disclosure, the trap passivation material may include fluorine (F). According to an embodiment of the present disclosure, the first gate electrode 401 may include a metal material containing fluorine. According to an embodiment of the present disclosure, the first gate electrode 401 may include titanium nitride (TIN) containing fluorine. According to an embodiment of the present disclosure, the first gate electrode 401 may include titanium tetrafluoride (TiF₄)-based titanium nitride. Thus, the first gate electrode 401 may include titanium nitride that is formed by using titanium tetrafluoride (TiF₄) as the source gas.

According to an embodiment of the present disclosure the content of the trap passivation material contained in the first gate electrode 401 may be adjusted in a range that the electrical characteristics of the semiconductor device are not deteriorated.

The low work function layer 501 may include a material that induces a low work function of the second gate electrode 201. For example, the low work function layer 501 may include polysilicon.

The second gate electrode 201 may include, for example, a metal material. In particular, according to an embodiment of the present disclosure the second gate electrode 201 may include a metal material containing a trap passivation material. The trap passivation material contained in the second gate electrode 201 may be diffused into the surrounding materials. The trap passivation material may be diffused into the inside of the gate dielectric layer 106 or into the interface between the gate electrode structure GE5 and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 500G is formed.

According to an embodiment of the present disclosure, the trap passivation material may include fluorine (F). According to an embodiment of the present disclosure, the second gate electrode 201 may include a metal material containing fluorine. According to an embodiment of the present disclosure, the second gate electrode 201 may include titanium nitride (TiN) containing fluorine. According to an embodiment of the present disclosure, the second gate electrode 201 may include titanium tetrafluoride (TiF₄)-based titanium nitride. Thus, the second gate electrode 201 may include titanium nitride that is formed by using titanium tetrafluoride (TiF₄) as the source gas.

According to an embodiment of the present disclosure the content of the trap passivation material contained in the second gate electrode 201 may be adjusted in a range that the electrical characteristics of the semiconductor device are not deteriorated.

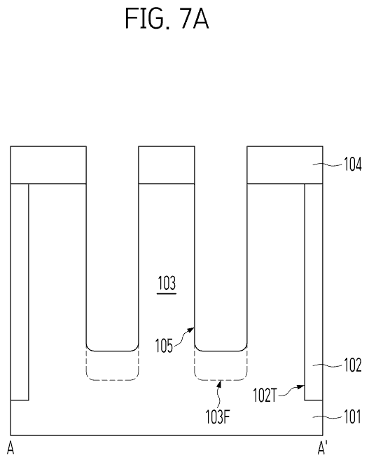

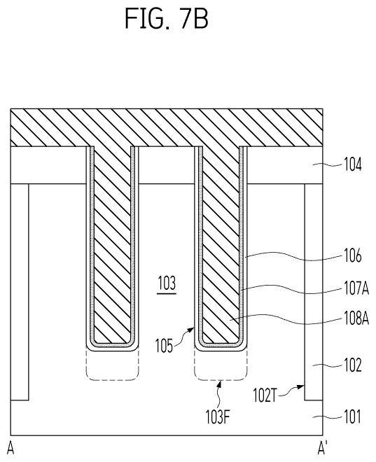

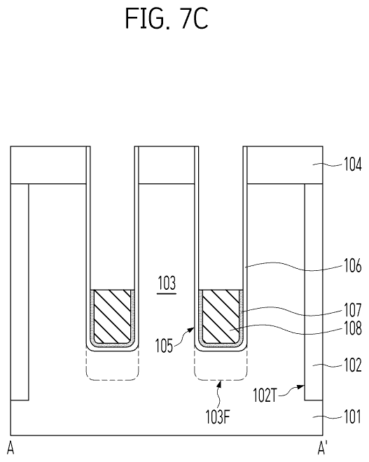

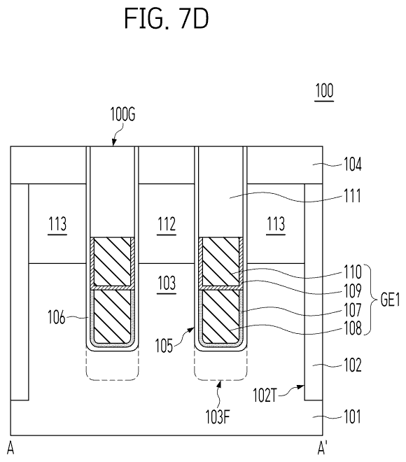

FIGS. 7A to 7D are process cross-sectional views illustrating a method for fabricating a semiconductor device in accordance with a first embodiment of the present disclosure. Thus, FIGS. 7A to 7D illustrate an example of the method for fabricating a semiconductor device shown in FIG. 2A.

Referring to FIG. 7A, an isolation layer 102 may be formed over the substrate 101. The active region 103 may be defined by the isolation layer 102. The isolation layer 102 may be formed by a Shallow Trench Isolation (STI) process. For example, an isolation trench 102T may be formed by etching the substrate 101. The isolation trench 102T may be filled with a dielectric material, thereby forming the isolation layer 102. The isolation layer 102 may include, for example, silicon oxide, silicon nitride, or a combination thereof. Chemical Vapor Deposition (CVD) or another deposition process may be used to fill the isolation trench 102T with a dielectric material. A planarization process, such as chemical mechanical polishing (CMP), may be additionally used.

A trench 105 may be formed in the substrate 101. The trench 105 may be formed in the line shape crossing the active region 103 and the isolation layer 102. The trench 105 may be formed by an etching process of the substrate 101 using the hard mask layer 104 as an etch mask. The hard mask layer 104 may be formed over the substrate 101 and may have a line-shaped opening. The hard mask layer 104 may be formed of a material having an etch selectivity with respect to the substrate 101. The hard mask layer 104 may be a silicon oxide, such as TEOS (Tetra Ethyl Ortho Silicate). The trench 105 may be formed shallower than the isolation trench 102T. The depth of the trench 105 may be sufficient to increase the average cross-sectional area of the subsequent gate electrode. As a result, the resistance of the gate electrode may be reduced. The bottom edge of trench 105 in accordance with another embodiment of the present disclosure may have a curvature.

Subsequently, a fin 103F may be formed. To form the fin 103F, the isolation layer 102 below the trench 105 may be selectively recessed. As for the structure of the fin 103F, the fin 103F illustrated in FIG. 2B may be referred to.

Referring to FIG. 7B, a gate dielectric layer 106 may be formed on the surface of the trench 105. Before the gate dielectric layer 106 is formed, any etch damage on the surface of the trench 105 may be repaired. For example, after a sacrificial oxide is formed through a thermal oxidation process, the sacrificial oxide may be removed. The gate dielectric layer 106 may be formed, for example, through a thermal oxidation process. The gate dielectric layer 106 may include, for example, silicon oxide. According to another example, the gate dielectric layer 106 may be formed by Chemical Vapor Deposition (CVD) or Atomic Layer Deposition (ALD). The gate dielectric layer 106 formed by a deposition process may include, for example, a high-k material, an oxide, a nitride, an oxynitride, or a combination thereof. The high-k material may include a hafnium-containing material. The hafnium-containing material may include hafnium oxide, hafnium silicon oxide, hafnium silicon oxynitride, or a combination thereof. According to another example, the high-k material may include lanthanum oxide, lanthanum aluminum oxide, zirconium oxide, zirconium silicon oxide, zirconium silicon oxynitride, aluminum oxide, or a combination thereof. As for the high-k material, other known high-k materials may selectively be used. In an embodiment, the gate dielectric layer 106 may include a stack of silicon oxide and a high-k material, where the high-k material may include a material with a higher oxygen atom planar density than silicon oxide.

Subsequently, a first barrier material layer 107A may be formed. The first barrier material layer 107A may be formed conformally on the profile of the surface of the gate dielectric layer 106. The first barrier material layer 107A may prevent oxidation of the gate electrode to be formed through a subsequent process and out-diffusion of the metal ions of the gate electrode. The first barrier material layer 107A may be formed of a material that is less oxidized than the gate electrode material and prevents diffusion of the gate electrode material. Thus, the first barrier material layer 107A may include a material having a lower electronegativity than the gate electrode material for preventing oxidation of the gate electrode and out-diffusion of the metal ions. The first barrier material layer 107A may include a high work function material. The first barrier material layer 107A may include a metal nitride. For example, the first barrier material layer 107A may include one metal nitride selected from among molybdenum nitride (MON), titanium nitride (TIN), and tantalum nitride (TaN).

Subsequently, a first gate material layer 108A may be formed over the first barrier material layer 107A to gap-fill the gate trench 105. The first gate material layer 108A may include, for example, a metal material. In particular, according to an embodiment of the present disclosure the first gate material layer 108A may include a metal material containing a trap passivation material. The trap passivation material contained in the first gate material layer 108A may be diffused into the surrounding materials. The trap passivation material may be diffused into the inside of the gate dielectric layer 106 or into the interface between the gate electrode and the gate dielectric layer 106. The diffused trap passivation material may passivate trap sites, thus, improving the retention and the row hammer characteristics of the semiconductor device.

The trap passivation material may be diffused by a subsequent thermal process. For example, the subsequent thermal process may be provided during the forming of the bit line structure and the capacitor following the forming of the buried gate structure.

According to an embodiment of the present disclosure, the trap passivation material may include fluorine (F). According to an embodiment of the present disclosure, the first gate material layer 108A may include a metal material containing fluorine. For example, the first gate material layer 108A may include molybdenum (Mo) containing fluorine. According to an embodiment of the present disclosure, the first gate material layer 108A may include molybdenum tetrafluoride (MoF₄)-based molybdenum. Thus, the first gate material layer 108A may include a molybdenum layer that is formed by using molybdenum tetrafluoride (MoF₄) as the source gas.

According to an embodiment of the present disclosure the content of the trap passivation material contained in the first gate material layer 108A may be adjusted in a range so that the electrical characteristics of the semiconductor device are not deteriorated.

As a comparative example, tungsten hexafluoride (WF₆)-based tungsten may deteriorate the electrical characteristics of a semiconductor device due to excessive fluorine. As another comparative example, since molybdenum tetrachloride (MoCl₄)-based molybdenum does not contain fluorine, the trap passivation effect that may be obtained from fluorine may not be obtained. In contrast, according to an embodiment of the present disclosure since molybdenum formed by using molybdenum tetrafluoride (MoF₄) as source gas is used as the first gate material layer 108A, the trap passivation effect may be obtained without deteriorating the characteristics of the semiconductor device that may be caused due to the excessive fluorine.

According to another embodiment of the present disclosure, the first gate material layer 108A may include titanium nitride (TIN) containing fluorine. According to an embodiment of the present disclosure, the first gate material layer 108A may include titanium tetrafluoride (TiF₄)-based titanium nitride. Thus, the first gate material layer 108A may include titanium nitride that is formed by using titanium tetrafluoride (TiF₄) as source gas.

Referring to FIG. 7C, a first gate electrode 108 may be formed to fill a bottom portion of the trench 105. The first gate electrode 108 may be formed, for example, by performing a recessing process onto the first gate material layer 108A (see FIG. 7B). The recessing process may be performed by a dry etching process, for example, an etch-back process. The etch-back process may be performed by using plasma. During the recessing process for forming the first gate electrode 108, the first barrier material layer 107A (see FIG. 7B) may also be etched to form the first barrier layer 107. The top surfaces of the first barrier layer 107 and the first gate electrode 108 may be disposed at the same level.

Referring to FIG. 7D, the second gate electrode 110 may be formed over the first gate electrode 108 to fill a middle portion of the trench 105. A second barrier layer 109 may be positioned between the second gate electrode 110 and the gate dielectric layer 106 and between the second gate electrode 110 and the first gate electrode 108.

The second gate electrode 110 may be formed through a series of processes of forming a second barrier material layer that conformally covers the surfaces of the first barrier layer 107, the first gate electrode 108, and the gate dielectric layer 106, forming a second gate material layer over the second barrier material layer, and leaving the second barrier material layer and the second gate material layer inside the trench 105 through a recessing process.

The second barrier layer 109 may include the same material as that of the first barrier layer 107. The second barrier layer 109 may prevent oxidation of the second gate electrode 110 and prevent out-diffusion of the metal material of the second gate electrode 110. To this end, the second barrier layer 109 may include a material that is less oxidized than the second gate electrode 110 and prevents diffusion of the second gate electrode 110. Thus, the second barrier layer 109 may include a material having a lower electronegativity than the second gate electrode 110 for preventing oxidation and out-diffusion of the second gate electrode 110. The second barrier layer molybdenum nitride (MON), titanium nitride (TIN), and tantalum nitride (TaN).

According to an embodiment of the present disclosure, the second barrier layer 109 may include a material which is different from the first barrier layer 107. The second barrier layer 109 may include a low work function material. The second barrier layer 109 may include a silicon-based material. For example, the second barrier layer 109 may include polysilicon.

According to an embodiment of the present disclosure, the second gate electrode 110 may include the same material as that of the first gate electrode 108. The second gate electrode 110 may fill a middle portion of the trench 105 over the first gate electrode 108. The second gate electrode 110 may include, for example, a metal material. In particular, according to an embodiment of the present disclosure the second gate electrode 110 may include a metal material containing a trap passivation material. The trap passivation material contained in the second gate electrode 110 may be diffused into the surrounding materials. The trap passivation material may be diffused into the inside of the gate dielectric layer 106 or into the interface between the gate electrode structure GE1 and the gate dielectric layer 106. The diffused trap passivation material may passivate the trap sites, thus, improving the retention and the row hammer characteristics of the semiconductor device.

The trap passivation material may be diffused by a subsequent thermal process. For example, the subsequent thermal process may be provided during formation of the bit line structure and the capacitor after the buried gate structure 100G is formed.

According to an embodiment of the present disclosure, the trap passivation material may include fluorine (F). According to an embodiment of the present disclosure, the second gate electrode 110 may include a metal material containing fluorine. According to an embodiment of the present disclosure, the second gate electrode 110 may include molybdenum (Mo) containing fluorine. According to an embodiment of the present disclosure, the second gate electrode 110 may include molybdenum fluoride (MoF₄)-based molybdenum. Thus, the second gate electrode 110 may include a molybdenum layer that is formed by using molybdenum fluoride (MoF₄) as a source gas.

According to an embodiment of the present disclosure the content of the trap passivation material contained in the second gate electrode 110 may be adjusted in a range so that does not deteriorate the electrical characteristics of the semiconductor device, such as resistance.

According to another embodiment of the present disclosure, the second gate electrode 110 may include titanium nitride (TiN) containing fluorine. According to an embodiment of the present disclosure, the second gate electrode 110 may include titanium tetrafluoride (TiF₄)-based titanium nitride. Thus, the second gate electrode 110 may include titanium nitride that is formed by using titanium tetrafluoride (TiF₄) as a source gas.

Subsequently, a capping layer 111 may be formed over the second gate electrode 110 to fill the upper portion of the trench 105. The capping layer 111 may include a dielectric material. For example, the capping layer 111 may include silicon nitride, silicon oxide, silicon oxynitride, or a combination thereof.

Through a series of fixing processes described above, a buried gate structure 100G including a gate dielectric layer 106 that covers the bottom surface and side walls of the trench 105, and a gate electrode structure GE1 and a capping layer 111 that are sequentially stacked to fill the trench 105 over the gate dielectric layer 106 may be formed.

Subsequently, a doping process of an impurity may be performed by an implantation process or other doping technology. As a result, the first doped region 112 and the second doped region 113 may be formed in the substrate 101. The first and second doped regions 112 and 113 may be referred to as first and second source/drain regions.

Subsequently, a bit line and a capacitor respectively coupled to the first doped region 112 and the second doped region 113 may be formed over the substrate 101.

According to an embodiment of the present disclosure the reliability of semiconductor devices may be improved by applying a gate electrode containing a trap passivation material.

According to an embodiment of the present disclosure the resistance of a word line may be reduced by applying a gate electrode containing a metal material.

According to an embodiment of the present disclosure gate-induced drain leakage (GIDL) may be reduced by adjusting the work functions of the upper and lower gate electrodes.

While the present invention has been described with respect to specific embodiments, it will be apparent to those skilled in the art that various changes and modifications may be made without departing from the spirit and scope of the present disclosure as defined in the following claims. Furthermore, the embodiments may be combined to form additional embodiments.

What is claimed is:

1. A semiconductor device, comprising:
a trench formed in a substrate;
a first gate electrode filling a lower portion of the trench, the first gate electrode containing a trap passivation material; and
a second gate electrode formed over the first gate electrode, the second gate electrode containing the trap passivation material.

2. The semiconductor device of claim 1, wherein the first and second gate electrodes are formed by using a source gas containing the trap passivation material.

3. The semiconductor device of claim 1, wherein the trap passivation material includes a material having a stronger binding force to oxygen than a metal.

4. The semiconductor device of claim 1, wherein the trap passivation material includes fluorine (F).

5. The semiconductor device of claim 1, wherein the first and second gate electrodes include a metal nitride.

6. The semiconductor device of claim 1, wherein the first and second gate electrodes include titanium nitride.

7. The semiconductor device of claim 5, further comprising:
a low work function layer covering both side walls and a bottom surface of the second gate electrode.

8. The semiconductor device of claim 7, wherein the low work function layer includes a material that induces a low work function of the second gate electrode.

9. The semiconductor device of claim 7, wherein the low work function layer includes polysilicon.

10. The semiconductor device of claim 1, wherein the first gate electrode includes a metal nitride, and
the second gate electrode includes a metal material.

11. The semiconductor device of claim 1, wherein the first gate electrode includes titanium nitride, and
the second gate electrode includes molybdenum.

12. The semiconductor device of claim 10, further comprising:
a barrier layer covering both side walls and a bottom surface of the second gate electrode.

13. The semiconductor device of claim 12, wherein the barrier layer includes a material capable of preventing oxidation of the second gate electrode and out-diffusion of metal ions.

14. The semiconductor device of claim 12, wherein the barrier layer includes a material having a lower electronegativity than the second gate electrode.

15. The semiconductor device of claim 12, wherein the barrier layer includes one silicon-based material selected from among silicon oxide and polysilicon.

16. The semiconductor device of claim 12, wherein the barrier layer is one metal nitride selected from among molybdenum nitride, titanium nitride, and tantalum nitride.

17. The semiconductor device of claim 1, wherein the first gate electrode includes a metal material, and
the second gate electrode includes a metal nitride.

18. The semiconductor device of claim 1, wherein the first gate electrode includes molybdenum, and
the second gate electrode includes titanium nitride.

19. The semiconductor device of claim 17, further comprising:
a barrier layer covering both side walls and a bottom surface of the first gate electrode.

20. The semiconductor device of claim 19, wherein the barrier layer includes a material capable of preventing oxidation of the first gate electrode and out-diffusion of metal ions.

21. The semiconductor device of claim 19, wherein the barrier layer includes a material having a lower electronegativity than the first gate electrode.

22. The semiconductor device of claim 19, wherein the barrier layer is one silicon-based material selected from among silicon oxide and polysilicon, or one metal nitride selected from among molybdenum nitride, titanium nitride, and tantalum nitride.

23. The semiconductor device of claim 17, further comprising:
an interface layer interposed between the first gate electrode and the second gate electrode.

24. The semiconductor device of claim 23, wherein the interface layer includes a silicon-based material.

25. The semiconductor device of claim 23, wherein the interface layer includes silicon oxide or polysilicon.

26. The semiconductor device of claim 1, wherein the first and second gate electrodes include a metal material.

27. The semiconductor device of claim 1, wherein the first and second gate electrodes contain molybdenum.

28. The semiconductor device of claim 26, further comprising:
a first barrier layer covering both side walls and a bottom surface of the first gate electrode; and
a second barrier layer covering both side walls and a bottom surface of the second gate electrode.

29. The semiconductor device of claim 28, wherein the first and second barrier layers include a material capable of preventing oxidation of the first and second gate electrodes and out-diffusion of metal ions, respectively.

30. The semiconductor device of claim 28, wherein the first and second barrier layers include a material having a lower electronegativity than the first and second gate electrodes, respectively.

31. The semiconductor device of claim 28, wherein the first and second barrier layers are one silicon-based material selected from among silicon oxide and polysilicon, or one metal nitride selected from among molybdenum nitride, titanium nitride, and tantalum nitride.
